(19) United States
(12) Patent Application Publication
(10) Pub. No.: US 2011/0023956 A1
(43) Pub. Date: Feb. 3, 2011

(54) REAR-CONTACT SOLAR CELL HAVING EXTENSIVE REAR SIDE EMITTER REGIONS AND METHOD FOR PRODUCING THE SAME

(76) Inventor: Nils-Peter Harder, Hameln (DE)

Correspondence Address: BIRCH STEWART KOLASCH & BIRCH, PO BOX 747, FALLS CHURCH, VA, 22040-0747, US

(21) Appl. No.: 12/747,450

(22) PCT Filed: Nov. 28, 2008
(86) PCT No.: PCT/EP08/66445

§ 371 Date: Aug. 26, 2010

(30) Foreign Application Priority Data
Dec. 11, 2007 (DE) 10 2007 059 487.0
Jun. 30, 2008 (DE) 10 2008 030 880.3

(51) Int. Cl. H01L 31/02; H01L 31/18

(52) U.S. Cl. 136/256; 438/98; 257/E31.111

(57) ABSTRACT

The invention relates to a rear-contact solar cell and to a method for producing the same. The rear-contact solar cell comprises a semiconductor substrate on the rear side surface of which emitter regions, contacted by emitter contacts, and base regions, contacted by base contacts, are defined. The emitter regions and the base regions overlap at least in overlap regions, the emitter regions in the overlap regions reaching deeper into the semiconductor substrate than the base regions, when seen from the rear side surface of the solar cell. As a result, a large area percentage of the rear side of the semiconductor substrate can be covered with a charge-collecting emitter, said emitter being at least partially buried in the interior of the semiconductor substrate so that there is no risk of the base contacts provoking a short circuit towards the buried emitter regions.

### FIELD OF THE INVENTION

The present invention relates to a rear-contact solar cell having extensive rear side emitter regions and also to a method for producing a rear-contact solar cell of this type.

### BACKGROUND TO THE INVENTION

Conventional solar cells have a front side contact, that is to say a contact arranged on a surface of the solar cell that faces the light, and a rear side contact on a surface of the solar cell that is turned away from the light. In these conventional solar cells, the largest volume fraction of a semiconductor substrate absorbing the light is of precisely the semiconductor type (for example p type) which is contacted by the rear side contact. This volume fraction is conventionally referred to as the base and the rear side contacts are therefore conventionally referred to as base contacts. A thin layer of the opposite semiconductor type (for example n type) is located in the region of the surface of the front side of the semiconductor substrate. This layer is conventionally referred to as the emitter and the contacts contacting it are referred to as emitter contacts.

In conventional solar cells of this type, the pn junction, which is crucial for the collection of current, is thus positioned just under the front side surface of the solar cell. This position of the pn junction is advantageous for an efficient collection of current in particular on use of semiconductor material of poor to moderate quality, as the highest generation rate of charge carrier pairs is present on the side of the solar cell that faces the light and most light-generated (minority) charge carriers thus have to cover only a short distance to the pn junction.

However, the emitter contacts arranged on the front side of the solar cell lead, on account of the partial shading associated therewith of the front side, to a loss in efficiency. In order to increase the efficiency of the solar cell, it is basically advantageous to arrange both the base contacts and the emitter contacts on the rear side of the solar cell. For this purpose, corresponding emitter regions have to be formed on the rear side of the solar cell. A solar cell in which both emitter regions and base regions are located on the side which is turned away from the light during use and in which both the emitter contacts and the base contacts are formed on the rear side is referred to as a rear-contact solar cell.

Rear-contact solar cells of this type, the current-collecting pn junction of which is arranged at least partly on the rear side of the solar cell, have to deal with the problem that both the emitter regions and the base regions are arranged next to one another on the rear side of the solar cell. Thus, the pn junction can no longer be formed along the entire surface of the solar cell; instead, the rear side emitter regions forming the pn junction together with the volume base region can now be formed only on a part of the rear side surface of the solar cell. Rear side base regions have to be provided therebetween for contacting the base.

As the diffusion length of the minority charge carriers to be collected by the pn junction is limited even in high-quality silicon, the area regions of the base regions provided on the rear side surface, which base regions substantially do not contribute to the formation of the charge carrier-collecting pn junction, should be as small as possible, in particular in solar cells whose current-collecting pn junction is arranged exclusively on the rear side of the solar cell, in order to adversely influence the effectiveness of the collection of current by the pn junction as little as possible. In this situation, the procedure is conventionally such that the largest area fraction of the rear side of the solar cell is provided with an emitter and only narrow base regions extend therebetween.

An example of a conventional rear-contact solar cell is illustrated schematically in cross section in FIG. 5. A semiconductor substrate 101 forms in its volume a base region for example of the p semiconductor type. Emitter regions 105 are formed on a rear side surface 103. The emitter regions 105 cover the majority of the rear side surface 103. Narrow, line-shaped regions, at which base regions 107 of the semiconductor substrate 101 reach up to the rear side surface 103, are left free between the elongate, finger-shaped emitter regions 105—to which the cross section of the solar cell as shown in the drawing runs perpendicularly. In the region of the rear side surface, these base regions can be more heavily doped than the bulk volume of the base of the solar cell. The entire rear side surface 103 is covered with a dielectric passivating layer 109 which can have a low index of refraction, so that it can serve for example as a rear side reflector for the solar cell, and which can for example be formed from silicon dioxide. The passivating layer 109 has local openings 111 through which emitter contacts 113 can contact the emitter regions 105. Furthermore, the dielectric layer 109 has openings 115 through which base contacts 117 can contact the base regions 107 which reach locally up to the rear side surface. The emitter contacts 113 and the base contacts 117 are separated from one another by narrow gaps 119 and thus electrically insulated.

In this type of solar cell, the base contacts 117 are slightly narrower than the base regions 107 on the rear side surface 103. This ensures that the base contact 117 cannot generate an undesired short circuit with the emitter regions 105 even when the dielectric layer 109 is not perfectly electrically insulated, as the base contacts do not overlap with the emitter regions 105 in projection.

In order to minimise production costs, in conventional rear-contact solar cells such as are illustrated in FIG. 5, the emitter contacts 113 and the base contacts 117 are generally applied in a common method step, for example by vapour depositing or sputtering-on of metal, if appropriate with subsequent electroplating, and are thus of substantially uniform thickness. However, the base contacts 117 are much narrower than the emitter contacts 113. However, as both contacts 113, 117 have to discharge the same current, it is the case that the emitter contacts are much thicker than required when applying a metal layer thickness for the contacts that is sufficient for an efficient dissipation of current from the base through the base contacts. In other words, an unnecessarily large amount of material is deposited on the more extensive emitter contacts when base and emitter contacts are deposited in a common process step. However, the application of the metal coating for the contacts and also the associated material costs are a considerable portion of the total costs of the solar cells.

It may therefore be desirable to form the metal contacts for both the emitter and the base contacts in roughly the same width and in this case to preferably make the metal contacts as wide as possible, so that an electrical resistance of the metal contacts that is as low as possible can be achieved at a low metal layer thickness.

In the alternative embodiment illustrated in FIG. 6 of a conventional rear-contact solar cell, the area fractions covered by the emitter contact 213 and by the base contact 217 respectively on the rear side surface of the semiconductor substrate 201 are substantially the same. As however, in this rear contact solar cell too, regions of the rear side surface that are as wide as possible are to be covered with emitter regions 205, the base regions 207 extending between the emitter regions 205 up to the rear side surface are narrower than the base contacts 217 contacting these regions. In other words, the base contacts 217 reach laterally into regions where they overlap the emitter regions 205. In order to avoid short circuits in the process, the dielectric layer 209 has to be as effective an electrical insulator as possible. However, the formation of a very effectively electrically insulating dielectric layer 209, which is in particular compatible with the steps for producing the solar cell and the loads placed on the solar cell in the module, has proven to be a considerable technological problem, in particular in view of the fact that local short circuits may be tolerated at no point on the area of the solar cell which, in currently industrially manufactured solar cells, typically comprises about 150 cm².

Furthermore, it has been observed that the emitter regions adjoining the rear side surface of the solar cell can be passivated only insufficiently by conventional processes such as thermal oxidation, in particular if the emitter regions are p-type emitters.

### SUMMARY OF THE INVENTION

There may therefore be a need for a rear-contact solar cell and for a method for producing a rear-contact solar cell in which the above-mentioned drawbacks of conventional rear-contact solar cells can be at least partly avoided. In particular, there may be a demand for a rear-contact solar cell which, on the one hand, displays good current-collecting properties on account of a rear side emitter which is as extensive as possible and in which, on the other hand, the rear side metal contacts can be applied in a beneficial manner and preferably at the same time the risk of local short circuits caused by the metal contacts can be minimised or surface passivation on the rear side of the solar cell can be improved.

This need may be met by the subject matter of the independent claims. Advantageous embodiments of the present invention are described in the dependent claims.

A first aspect of the present invention describes a rear-contact solar cell having a semiconductor substrate, emitter regions along a rear side surface of the semiconductor substrate, base regions along the rear side surface of the semiconductor substrate, emitter contacts for electrically contacting the emitter regions and base contacts for electrically contacting at least some of the base regions. The semiconductor substrate has a base semiconductor type which may be either an n semiconductor type or a p semiconductor type. The base regions likewise have the base semiconductor type. The emitter regions have an emitter semiconductor type opposite to the base semiconductor type. The emitter and base regions formed on the rear side surface overlap at least in overlap regions, the emitter regions in the overlap regions reaching from the rear side surface deeper into the semiconductor substrate than the base regions.

This first aspect of the present invention may be regarded as being based on the following idea: Both emitter and base regions, which can both be electrically contacted by corresponding contacts on the rear side surface, are formed on the rear side surface of the semiconductor substrate. The fact that the emitter regions and the base regions laterally overlap in overlap regions and the emitter regions can run deeper there in the interior of the semiconductor substrate, whereas the base regions extend on the rear side surface of the semiconductor substrate, allows aims to be pursued that appear to be mutually contradictory in conventional rear-contact solar cells.

On the one hand, the base regions contacted by the base contacts can be formed so as to be comparatively wide or extensive on the rear side surface. In particular, the base regions can take up roughly the same area of the rear side surface as or a slightly larger area of the rear side surface than the base contacts, so that it is not absolutely crucial to electrically insulate the base contacts against the substrate surface by a dielectric layer arranged thereunder. In principle, the entire base region can be directly connected on its rear side surface to the corresponding base contacts without undesired short circuits occurring.

On the other hand, the area fraction of the base regions on the rear side surface of the semiconductor substrate, and thus also the area fraction of the base contacts, may be roughly the same size as the area fraction of the emitter partial regions or the emitter contacts adjoining the rear side surface. Thus, both the emitter contacts and the base contacts can each be formed at the same thickness necessary to avoid substantial series resistance losses in the contacts.

In the described rear-contact solar cell, a very large fraction of the rear side surface can in this case be covered with emitters on account of the emitter regions partly overlapping the base regions, so that the charge carrier-collecting properties can be very good on account of the extensive pn junction.

According to an exemplary embodiment which will be described hereinafter in greater detail, the emitter regions and the base regions can be formed by means of two successive diffusions of doping materials into the semiconductor substrate for producing a rear-contact solar cell according to the invention and in particular the overlap regions formed therein. In this case, the emitter regions can firstly be diffused in a first diffusion step, either small partial regions, in which the base regions on the rear side surface that are to be subsequently produced are to be in electrical contact with the base regions located further in the interior of the semiconductor substrate, being locally protected from the emitter diffusion or the emitter regions subsequently being locally opened/removed at these locations. In a second diffusion step, the base regions can then be formed on the rear side surface of the semiconductor substrate.

In this case, use may be made of what is known as the “emitter push effect” in which, in two successive process steps for diffusing doping materials into silicon for example, the second diffusion, albeit of the same or greater intensity, does not necessarily compensate or overcompensate for the first diffusion, as the second diffusion can push some of the doping materials of the first diffusion ahead of itself. In other words, the emitter push effect may cause the doping materials introduced during the first diffusion for producing the emitter regions to diffuse further into the interior of the semiconductor substrate, whereas the doping materials for producing the base regions diffuse-in from the surface of the semiconductor substrate. This can provide a structure in which the emitter regions and the base regions have roughly the same concentrations of dopants, but the emitter regions are arranged further in the interior of the semiconductor substrate than the base regions arranged on the surface, so that the desired overlap can occur. Experience has shown that the emitter push effect is very pronounced in particular when the second diffusion layer is a phosphorus diffusion.

Alternatively, the overlapping structure may be achieved in that firstly a deep emitter is formed and subsequently shallower base regions are produced in the region of base contacts to be subsequently produced, the base regions being produced in such a way that the emitter doping which was beforehand originally contained in these regions is locally overcompensated. Because the initially produced the emitter was formed deeper than the subsequently overcompensated base regions, the desired overlap of the two regions may again occur.

Doping materials can be introduced into the semiconductor substrate into the desired regions and depths also by other methods, such as for example ion implantation, instead of diffusion processes. As a further alternative, the structures according to the invention can also be produced by applying and structuring (or by applying in a structured manner) semiconductor layers by means of coating methods, for example epitaxy, heteroepitaxy or other coating methods.

Further features, details and possible advantages of embodiments of the rear-contact solar cell according to the invention will be described hereinafter.

The semiconductor substrate used for the rear-contact solar cell may for example be a monocrystalline or multicrystalline silicon wafer. Alternatively, thin layers made of amorphous or crystalline silicon or of other semiconducting materials can be used as the substrate.

Some of the emitter regions can extend along the rear side surface of the semiconductor substrate directly on the surface; however, parts of the emitter regions, in particular in the overlap regions, can also not directly adjoin the surface, but extend somewhat deeper in the interior of the semiconductor substrate. These internally “buried” emitter regions can be in electrical contact with the regions of the emitter regions that adjoin the rear side surface, so that they can also be electrically contacted from there by the emitter contacts.

The emitter regions can be produced by diffusing dopants into the semiconductor substrate. For example, an n-type emitter region can be produced in a p-type semiconductor substrate by local diffusion of phosphorus. However, alternatively, the emitter regions can also be produced by other methods such as for example by ion implantation or alloying, thus producing what is known as a homojunction, that is to say a pn junction with oppositely doped regions of the same semiconductor basic material, for example silicon. Alternatively, the emitter regions can also be deposited epitaxially, for example be vapour deposited or sputtered-on, thus producing, depending on the selection of the applied material, homojunctions or what are known as heterojunctions, that is to say pn junctions between a base semiconductor-type first semiconductor material and an emitter semiconductor-type second semiconductor material, which are referred to as heterojunctions when the base and emitter semiconductors differ by more than just the conduction type (doping type). A possible example are emitter regions made of amorphous silicon (a-Si) which is vapour deposited or applied by means of PECVD on a semiconductor substrate made of crystalline silicon (c-Si).

The base regions can also be produced by means of one of the above-mentioned production methods, although production by local diffusing-in of a dopant to form the base regions may be preferred.

The emitter regions and the base regions can each have, viewed from above onto the rear side surface of the semiconductor substrate, a comb-like structure in which in each case linear, finger-like emitter regions adjoin adjacent linear, finger-like base regions. A nested structure of this type is also said to be “interdigitated”.

Both the emitter contacts and the base contacts can each be formed in the form of a local metal coating, for example in the form of finger-like grids. For this purpose, metals, such as for example silver or aluminium, can be deposited onto the base or emitter regions locally, for example through a mask or using photolithography, for example by vapour deposition or sputtering-on, or the metal contacts can be applied in the desired structure by a printing method such as screen printing or a dispensing method. In order to avoid short circuits between the emitter contacts and the base contacts, a respective electrically insulating gap can be provided between the two. This result can also be achieved by a metal layer which is applied over the entire surface and afterwards locally removed along the line of the desired contact separation.

An essential feature for the rear-contact solar cell according to the invention are the overlap regions in which both a base region and an emitter region are located on the rear side of the semiconductor substrate in the projection onto the rear side surface. In this case, the base region directly adjoins the rear side surface, whereas the emitter region is displaced in this region further into the interior of the semiconductor substrate, so that the emitter in this region can also be referred to as a “buried emitter”. Both regions can in this case extend very close to the rear side surface of the semiconductor substrate, in particular in view of the thickness of the semiconductor substrate, which is conventionally high compared to the thickness of the emitter or base regions of for example a few micrometres and can form about 200 μm in a silicon wafer, for example. However, the emitter region can extend deeper into the semiconductor substrate than the base regions, in particular in the overlap regions. For example, the emitter region can extend down to a depth of more than 1 μm, preferably more than 2 μm below the rear side surface, whereas the base regions reach into the semiconductor substrate for example to a depth of merely less than 1 μm, for example a depth of about 0.5 μm.

In the fully processed solar cell, the emitter regions do not extend along the entire rear side surface of the semiconductor substrate; instead, there remain therebetween small local regions which do not have the emitter semiconductor type and which later serve to produce an electrical connection between the base regions formed on the rear side surface and the base regions in the interior of the semiconductor substrate. These connecting regions, either in which no corresponding emitter doping was caused as early as during the production of the emitter regions or in which previously produced emitter doping was subsequently removed, for example by etching-away or by laser ablation, or by local overcompensation of the emitter doping by base doping, may be line-like, for example parallel to the base contacts to be formed later, or dot-shaped.

According to one embodiment of the present invention, the emitter regions extend along more than 60%, preferably more than 70%, even more preferably more than 80% and more preferably still more than 90% of the rear side surface of the semiconductor substrate and the base regions extend along more than 25%, preferably more than 40% and more preferably between 45% and 55% of the rear side surface of the semiconductor substrate.

As a result of the fact that the emitter regions and the base regions partly overlap, the total area of the emitter regions facing the main volume and the base regions facing the rear side of the cell can add up to more than 100% of the rear side surface of the semiconductor substrate. The further the emitter and base regions overlap in this case, the greater the area fraction of the emitter regions and the base regions may at the same time be. The greater the area fraction of the emitter regions is in this case, the more efficiently the minority charge carriers, which are produced in the interior of the semiconductor substrate by incident light, can be collected by the pn junction produced at the junction between the emitter region and the base region in the interior of the semiconductor substrate; this contributes to a high current density of the rear-contact solar cell. On the other hand, the greater the area fraction of the base regions facing the rear side of the cell is, the more extensive the base contacts covering these base regions may also be without producing short circuits to the emitter regions even if there is no electrically effectively insulating layer on the rear side of the solar cell. In elongate, finger-like contacts, this means that the base contacts may be correspondingly wide without there being a risk of overlap with laterally adjacent emitter regions. On account of the high width of the base contacts, series resistance losses in the metal contacts can be minimised even at relatively low metal layer thicknesses.

According to a further embodiment of the present invention, an area of the rear side surface of the semiconductor substrate that is covered by the base contacts can be between 70% and 100% of the area of the base regions on the rear side surface of the semiconductor substrate. In other words, 70% to 100%, preferably 90% to 98%, of the area of the base regions can be covered by base contacts. Low series resistances can be implemented in these contacts on account of the large area of the base contacts that is possible as a result. On the other hand, the base contacts preferably do not protrude laterally beyond the base regions positioned thereunder in order to avoid any short circuits between the base contacts and the emitter regions located next to the base regions.

According to a further embodiment of the present invention, a doping concentration is higher in the base regions on the rear side surface of the semiconductor substrate than in base regions in the interior of the semiconductor substrate. This can result from the fact that the base regions on the rear side surface are subsequently introduced, for example are diffused, into the semiconductor substrate during production of the solar cell. Heavily doped superficial base regions of this type can act as BSFs (back surface fields). For example, the doping concentration in the interior of the semiconductor substrate may be in the range of from 1×10¹⁴ cm⁻³ to 1×10¹⁷ cm⁻³, whereas the doping concentration in the base regions on the rear side surface may be greater than 1×10¹⁸ cm⁻³, preferably greater than 1×10¹⁹ cm⁻³. In addition to the BSF properties of such heavily doped base regions, comparatively extensive pn junctions between heavily doped emitter and base regions can be produced in the overlap regions. As described in greater detail in a patent application in the name of the applicant filed at the same time as the present application, planar p⁺n⁺ junctions of this type can act as Zener diodes which can provide the function of a bypass diode for the solar cell.

According to a further embodiment of the present invention, a doping concentration is higher in the base regions on the rear side surface of the semiconductor substrate than in the emitter regions. This applies in particular when the base regions are formed by local overcompensation of previously formed emitter regions.

If, for example, an emitter region having a doping concentration of 5×10¹⁸ cm⁻³ is produced, a base region having a doping concentration of for example more than 2×10¹⁹ cm⁻³ can subsequently be produced in a partial region of the emitter region by overcompensation with dopants for the correspondingly opposite type of semiconductor.

According to a further embodiment of the present invention, an area of the rear side surface of the semiconductor substrate that is contacted by the emitter contacts differs by less than 30%, preferably less than 20% relative, even more preferably less than 10% relative, from an area of the rear side surface of the semiconductor substrate that is contacted by the base contact. In other words, the emitter contacts and the base contacts are roughly similar or the same size in terms of area, both the emitter contacts and the base contacts each ideally covering approximately 50% of the rear side surface of the semiconductor substrate. Because both types of contact are roughly the same size in terms of area, the series resistances, which are effected in the contacts and are dependent both on the lateral area extent and on the thickness of the contacts, may also be roughly the same size. Both types of contact can be produced at the same thickness, wherein the thickness can be selected in such a way that the series resistance losses in the contacts are negligibly low. Even if the two types of contact are produced in the same method step and thus automatically have the same thickness, neither of the types of contact has an excessively high thickness and no metal necessary for producing the contacts is wasted.

According to a further embodiment of the present invention, regions in which base regions on the rear side surface of the semiconductor substrate contact base regions in the interior of the semiconductor substrate are formed as dot-shaped connecting regions. The connecting regions interrupt in this regard the regions of overlap between the emitter regions and the base regions and can thus act as an electrical connection between the base contacts contacting the base regions and the base regions in the interior of the semiconductor substrate. The fact that these connecting regions are formed in a dot-shaped manner allows the interruptions in the emitter region to be as small as possible, so that the area of the current-collecting pn junction is maximised. For example, the dot-shaped connecting regions can be formed linearly one after another and set equidistantly apart from one another parallel to finger-shaped base contacts.

According to a further embodiment of the present invention, the aforementioned dot-shaped connecting regions are each arranged in lateral edge regions of the base regions on the rear side surface of the semiconductor substrate. Because connecting regions are formed not in the centre, but in lateral edge regions of the base regions, the distances which charge carriers, which were produced in the interior of the semiconductor substrate by incidence of light, have to travel before they can flow away to the base contacts through the connecting regions can be reduced. A reduced series resistance within the base can be achieved as a result.

According to a further embodiment of the present invention, the base regions are phosphorus-doped and the emitter regions are boron-doped. A configuration of this type allows the emitter regions to be produced first and the phosphorus-doped base regions then to be diffused-in and the emitter push effect thereby to be utilised, that is to say the boron doping, which was produced beforehand in the emitter regions, to be driven further into the interior of the semiconductor substrate. In this way, the overlap regions can be produced in a procedurally simple manner.

According to a further embodiment of the present invention, the emitter regions adjoin the rear side surface substantially merely in the region of the emitter contacts. In other words, the emitter regions extend substantially merely in those areas where they are contacted by the emitter contacts, directly on the rear side surface of the solar cell, and in all other regions the emitter regions are “buried” deeper in the interior of the solar cell and separated from the rear side surface by a base region positioned therebetween. To put it in still another way, the overlap regions reach in this embodiment laterally just up to the regions of the emitter regions that are contacted by the emitter contacts.

The term “substantially” may in this regard be interpreted to mean that the regions of the emitter regions that adjoin the rear side surface correspond, with accuracy allowing for manufacturing tolerances, i.e. with accuracy from within a few micrometres to within a few hundred micrometres depending on the production method, to the regions of the rear side surface that are contacted by the emitter contacts. In this embodiment, the area fraction of the regions of the emitter regions that adjoin the rear side surface is at least to be less than the area fraction of the regions of the emitter regions that do not adjoin the rear side surface, i.e. are buried.

Thus, in this embodiment, a large part of the rear side surface is covered with base regions. These base regions may be surface-passivated more effectively, in particular if they are n-type regions, than p-type emitter regions using established processes such as for example thermal oxidation.

According to a further embodiment of the present invention, at least some of the base regions are not in electrical contact with base contacts. In other words, not all of the base regions on the rear side surface are in electrical contact with the base contacts; instead, some base regions are insulated from the base contacts. These regions which are not directly contacted are also referred to as floating regions and may be surface-passivated particularly effectively, in particular if they are n-type regions.

A further aspect of the present invention proposes a method for producing a solar cell, in particular the above-described solar cell according to the invention, the method including the following process steps: providing a semiconductor substrate having a base semiconductor type; forming emitter regions along a rear side surface of the semiconductor substrate, the emitter regions having an emitter semiconductor type opposite to the base semiconductor type; forming base regions along the rear side surface of the semiconductor substrate, the base regions having the base semiconductor type; forming emitter contacts for electrically contacting the emitter regions; and forming base contacts for electrically contacting at least some of the base regions. In this regard, the emitter regions and the base regions are formed in such a way that they overlap at least in overlap regions and the emitter regions in the overlap regions reach, viewed from the rear side surface, deeper into the semiconductor substrate than the base regions.

The emitter regions and the base regions can be produced by means of different methods, for example by locally diffusing-in using for example masks or lithography, by ion implantation, by local alloying-in, by epitaxial application of corresponding layers, by application over the entire surface area and subsequent structuring, e.g. local removal for example by means of laser ablation, etc.

The emitter and base contacts can likewise be formed by means of various methods, for example by local vapour deposition, for example using masks or lithography, or by screen printing or by dispensing methods. Generally, use may be made of all methods allowing contacts to be formed locally, for example in a finger or grid-shaped manner, on a rear side of a substrate, including the possibility of applying over the entire surface area metal layers which are subsequently structured by local removal.

According to one embodiment of the present invention, first the emitter regions having a first depth and a first doping concentration and then the base regions having a second depth and a second doping concentration are formed, the first depth being greater than the second depth and the first doping concentration being less than the second doping concentration. In other words, a relatively lightly doped, deep emitter is firstly formed and can then be locally overcompensated by a more heavily doped, flatter base region. In this case, emitter regions positioned deeper outside the overcompensated regions can remain, so that the desired overlap region is formed.

According to a further embodiment of the present invention the (buried) emitter regions which are positioned deeper, viewed from the rear side of the solar cell, are produced not in that a deep emitter is formed and overcompensated close to the surface, but rather directly, for example by means of ion implantation of doping materials, at the desired depth.

According to a further embodiment of the present invention, the emitter regions are formed first with a boron doping and the base regions are formed subsequently with a phosphorous doping. In this regard, it is not compulsory for the base regions to be produced by overcompensation of the previously produced emitter regions. Instead, the emitter push effect can be utilised in this embodiment, wherein during the diffusing-in of the phosphorus doping the boron doping, which was present beforehand there, is pushed ahead and forms an emitter region positioned deeper. Accordingly, it is not imperative for the doping concentration to be greater in the base regions than in the emitter regions.

According to a further embodiment of the present invention, at least some of the base regions are formed in such a way that they are not in electrical contact with base contacts. In this way, it is possible to form what are known as “floating” base regions which may be effectively surface-passivated, in particular in the case of n-type base regions. The floating base regions can be electrically insulated from the base regions contacted by the base contacts by emitter regions or other insulating layers positioned therebetween.

It should be noted that the embodiments, features and advantages of the invention have been described mainly in relation to the rear-contact solar cell according to the invention. However, a person skilled in the art will recognise from the foregoing and also from the following description that, unless otherwise indicated, the embodiments and features of the invention are also similarly transferable to the method according to the invention for producing a solar cell. In particular, the features of the various embodiments may also be combined with one another in any desired manner.

### BRIEF DESCRIPTION OF THE DRAWINGS

Further features and advantages of the present invention will become apparent to the person skilled in the art from the following description of exemplary embodiments (although these are not to be interpreted as restricting the invention) and with reference to the accompanying drawings.

FIG. 1 is a cross-sectional illustration of a rear-contact solar cell according to one embodiment of the present invention with overcompensated base regions.

FIG. 2 is a cross-sectional illustration of a rear-contact solar cell according to a further embodiment of the present invention with overlap regions produced by the emitter push effect.

FIG. 3 is a cross-sectional illustration of a rear-contact solar cell according to a further embodiment of the present invention with connecting regions formed in edge regions of the base regions.

FIG. 4 is a detail-type plan view onto the rear side of the embodiment illustrated in FIG. 3.

FIG. 5 is a cross-sectional illustration of a rear-contact solar cell according to a further embodiment of the present invention in which overlap regions reach close to the emitter contacts.

FIG. 6 is a cross-sectional illustration of a rear-contact solar cell according to a further embodiment of the present invention with floating base regions.

FIG. 7 shows a rear-contact solar cell according to the prior art.

FIG. 8 shows a further rear-contact solar cell according to the prior art.

All the figures are merely schematic and not true-to-scale. In the figures, similar or identical elements are denoted by the same reference numerals.

### DETAILED DESCRIPTION OF PREFERRED EMBODIMENTS

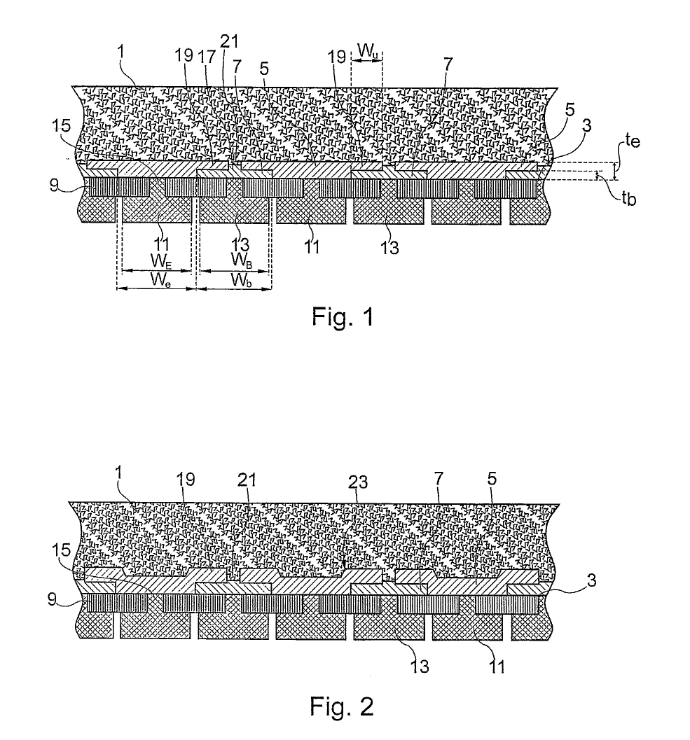

The rear-contact solar cell according to the invention shown in cross section in FIG. 1 has a semiconductor substrate 1 in the form of a silicon wafer. Both emitter regions 5 and base regions 7 are formed on the rear side surface 3 of the semiconductor substrate 1. A dielectric layer 9 made of silicon oxide or silicon nitride, which can serve to passivate the surface of the semiconductor substrate and/or as a rear side reflector, but does not necessarily have to be electrically insulating, is also located on the rear side surface 3. The emitter contacts 11 and the base contacts 13 are then formed over the dielectric layer 9. Both the emitter and the base contacts 11, 13 are formed in the form of elongate, finger-shaped contacts running perpendicularly to the plane of the drawing. They have substantially the same widths w_{E}, w_{B}. The emitter contact 11 contacts an emitter region 5 through line-shaped openings or through dot-shaped openings 15, which are adjacently arranged linearly one after another, in the dielectric layer 9. The width wₑ of the partial region of the emitter region 5 that adjoins the rear side surface 3 is slightly greater than the width w_{E} of the corresponding emitter contact 11. Accordingly, there is no risk of the emitter contact 11 causing a short circuit to the adjacent base region 7 even when the dielectric layer 9 is not electrically insulating. Similarly, a finger-shaped base contact 13 extends via the dielectric layer 9 and contacts the base region 7 positioned thereunder through a line-shaped opening or through dot-shaped openings 17 which are adjacently arranged linearly one after another. In this case too, the width w_{B} of the base contact 13 is slightly less than the width w_{b} of the base region 7 positioned thereunder, so that there is no risk of short circuits between metal contacts of one polarity and semiconductor regions of the other polarity, i.e. for example between base contacts and emitter regions.

In overlap regions 19, the emitter region 15 overlaps a laterally adjoining base region 7. This overlap region 19 is in this regard produced in that, for producing the rear-contact solar cell shown, firstly the emitter regions 5 having a comparatively deep depth tₑ were diffused into the rear side of the semiconductor substrate 1 and subsequently the base regions 7 having a shallower depth t_{b} were diffused-in, the diffusion of the base regions due to the process parameters used in this case, such as for example temperature and diffusion duration, being carried out in such a way that in the region of the base regions 7 overcompensation of the emitter doping located there takes place.

The overlap regions 19 have a width wᵤ which is slightly less than half the width w_{b} of the base regions 7. A small gap, which acts as a connecting region 21 and at which the corresponding base region 7 is electrically contacted with the interior of the semiconductor substrate 1 and via which the majority charge carriers produced in the semiconductor substrate 1 can flow toward the base contact 13, is thus left between opposing overlap regions 19.

The embodiment illustrated in FIG. 2 of the rear-contact cell according to the invention corresponds in most of its features to the embodiment shown in FIG. 1. The main difference is the step-shaped junction 23 which may be seen in the emitter region 5 at the edge of the overlap region 19. This junction 23 is produced when the emitter push effect is utilised during the production of the emitter regions 5 and the base regions 7 and thus, as the base region 7 diffuses-in, the emitter region 5 positioned thereover is pushed in the overlap region 19 deeper into the interior of the semiconductor substrate 1.

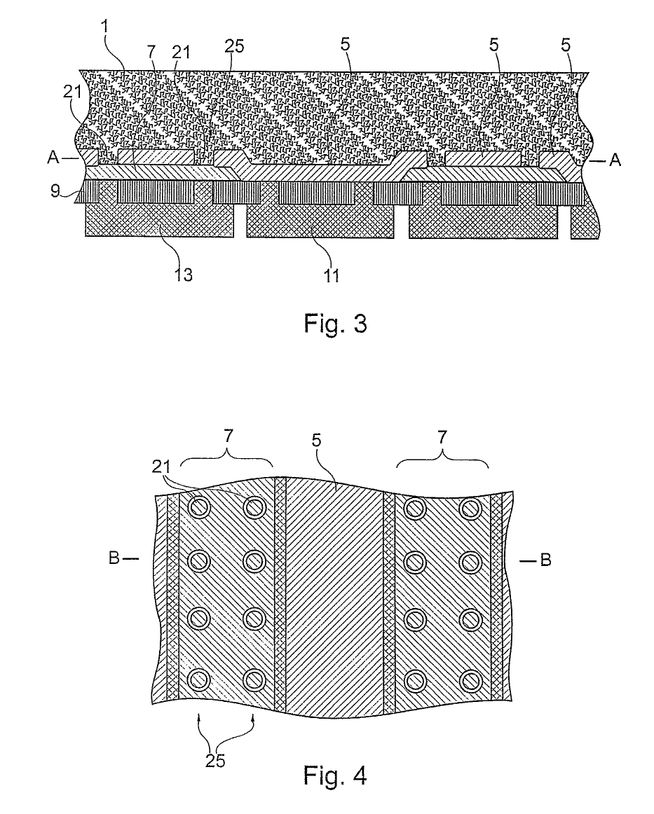

The embodiment shown in FIGS. 3 and 4 of the rear-contact solar cell according to the invention differs from the embodiments described hereinbefore mainly in that the connecting region 21, which connects the base region 7 arranged on the rear side surface 3 to the interior of the semiconductor substrate 1, is not arranged roughly in the centre of the base region 7 as shown in FIGS. 1 and 2. Instead, two connecting regions 21 of this type are provided that are each provided in edge regions 25 of the base regions 7 and preferably do not form long lines running parallel to the metal contacts, but rather are particularly preferably dot-shaped connecting regions. As a result, majority charge carriers, which are produced in the interior of the semiconductor substrate 1 in a region above the emitter regions 5, that is to say between two laterally adjacent base regions 7, can for example flow away toward the base contact 13 through the connecting regions 21 provided in the edge region 25, instead of having to flow, as in the embodiment shown in FIGS. 1 and 2, over a longer distance up to the connecting region 21 provided in the centre of the base region 7 before they can flow away to the base contact 13. Accordingly, serial resistance losses can be reduced as a result.

As a result of the fact that the connecting regions 21 are formed in this embodiment merely in a dot-shaped manner, there is also an electrical contact of the regions of the emitter regions 5 that are arranged centrally over the base contacts 13 to the regions of the emitter regions 5 that are electrically contacted with the emitter contacts 11. Apart from the small recesses on the connecting regions 21, substantially the entire surface of the solar cell can thus be covered with an emitter 5, so that charge carriers can be collected very efficiently.

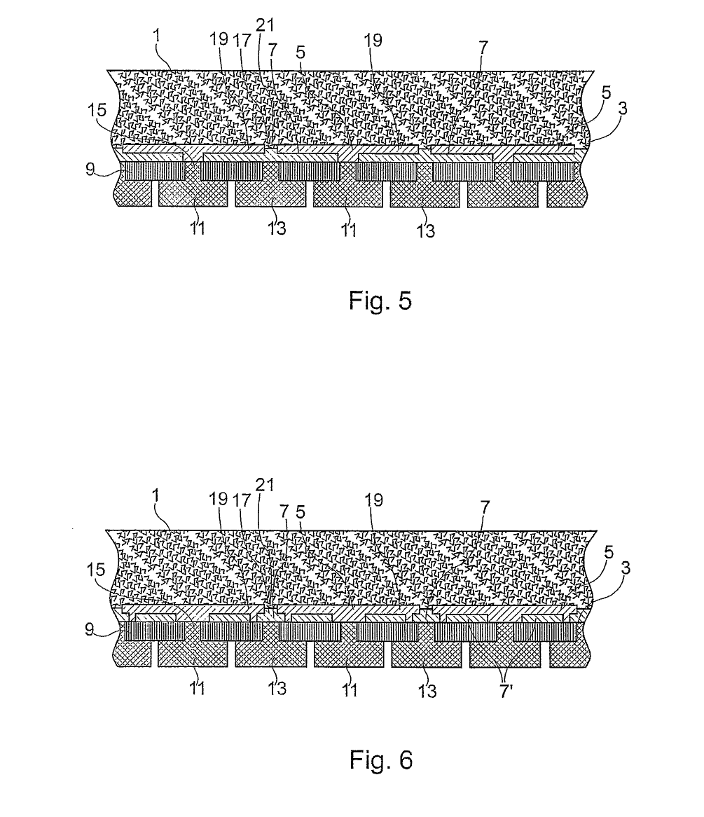

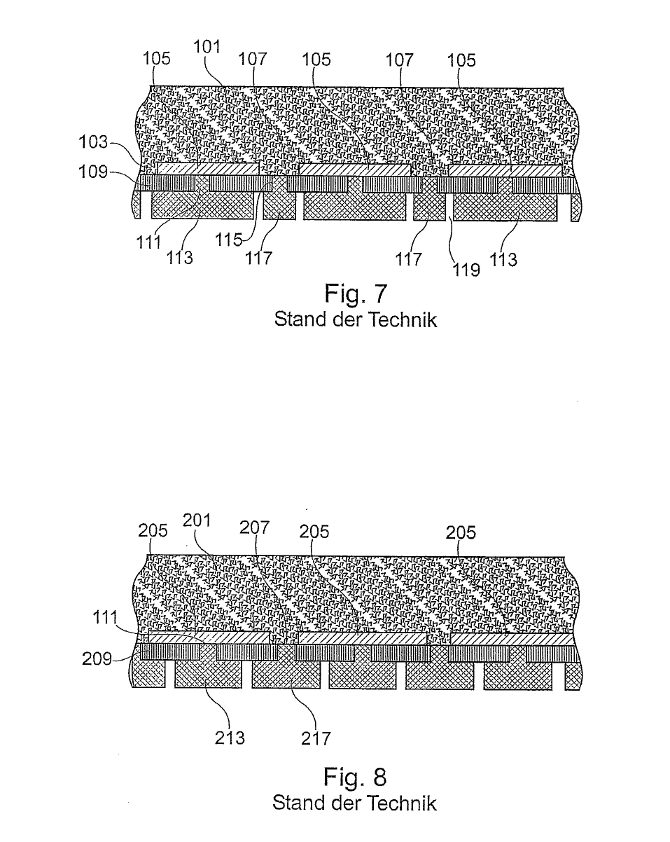

FIG. 5 shows an embodiment in which the emitter regions 5 adjoin the rear side surface 3 merely in the region of the emitter contacts 11. In the regions positioned therebetween, the emitter regions 5 are buried deeper in the interior of the solar cell and separated from the rear side surface 3 by base regions 7 positioned therebetween. These base regions 7 are in turn covered by a dielectric layer 9, preferably a thermal oxide, and are as a result surface-passivated very effectively.

FIG. 6 shows an embodiment in which some of the base regions 7 are not electrically contacted with base contacts 13. These “floating” base regions 7′ are insulated from the contacted base regions 7 by parts of the emitter regions 5. The floating base regions 7′ can be passivated very effectively by a dielectric layer 9 deposited thereon.

Finally, reference is made to the fact that the terms “comprise”, “have”, etc. do not rule out the presence of further elements. The term “a(n)” does not rule out the presence of a plurality of items either. The reference numerals in the claims serve merely to improve readability and are not in any way intended to restrict the scope of protection of the claims.

1. Rear-contact solar cell, having:
a semiconductor substrate;
base regions along the rear side surface of the semiconductor substrate, the base regions having a base semiconductor type;
emitter regions along a rear side surface of the semiconductor substrate, the emitter regions having an emitter semiconductor type opposite to the base semiconductor type;
emitter contacts for electrically contacting the emitter regions;
base contacts for electrically contacting at least some of the base regions;
wherein the emitter regions and the base regions overlap at least in overlap regions and wherein the emitter regions in the overlap regions reach from the rear side surface deeper into the semiconductor substrate than the base regions.

2. Rear-contact solar cell according to claim 1, wherein the emitter regions extend along more than 65% of the rear side surface of the semiconductor substrate and wherein the base regions extend along more than 40% of the rear side surface of the semiconductor substrate.

3. Rear-contact solar cell according to claim 1, wherein an area of the rear side surface of the semiconductor substrate that is covered by the base contacts is between 50% and 100% of the area of the base regions on the rear side surface of the semiconductor substrate.

4. Rear-contact solar cell according to claim 1, wherein a doping concentration is higher in the base regions on the rear side surface of the semiconductor substrate than in base regions in the interior of the semiconductor substrate.

5. Rear-contact solar cell according to claim 1, wherein a doping concentration is higher in the base regions on the rear side surface of the semiconductor substrate than in emitter regions.

6. Rear-contact solar cell according to claim 1, wherein an area of the rear side surface of the semiconductor substrate that is contacted by the emitter contact differs by less than 20% relative from an area of the rear side surface of the semiconductor substrate that is contacted by the base contact.

7. Rear-contact solar cell according to claim 1, wherein regions in which base regions on the rear side surface of the semiconductor substrate (1) contact base regions in the interior of the semiconductor substrate are formed as dot-shaped connecting regions.

8. Rear-contact solar cell according to claim 7, wherein the dot-shaped connecting regions are each arranged in lateral edge regions of the base regions on the rear side surface of the semiconductor substrate.

9. Rear-contact solar cell according to claim 1, wherein the base regions are phosphorus-doped and the emitter regions are boron-doped.

10. Rear-contact solar cell according to claim 1, wherein the emitter regions adjoin the rear side surface substantially merely in the region of the emitter contacts.

11. Rear-contact solar cell according to claim 1, wherein at least some of the base regions are not in electrical contact with base contacts.

12. Method for producing a solar cell, including:
providing a semiconductor substrate;
forming base regions along the rear side surface of the semiconductor substrate, the base regions having a base semiconductor type;
forming emitter regions along a rear side surface of the semiconductor substrate, the emitter regions having an emitter semiconductor type opposite to the base semiconductor type;
forming emitter contacts for electrically contacting the emitter regions;
forming base contacts for electrically contacting at least some of the base regions;
wherein the emitter regions and the base regions are formed in such a way that they overlap at least in overlap regions and the emitter regions in the overlap regions reach from the rear side surface deeper into the semiconductor substrate (than the base regions).

13. Method according to claim 12, wherein first the emitter regions having a first depth and a first doping concentration and then the base regions having a second depth and a second doping concentration are formed, the first depth being greater than the second depth and the first doping concentration being less than the second doping concentration.

14. Method according to claim 12, wherein first the emitter regions are formed with a boron doping and then the base regions are formed with a phosphorous doping.

15. Method according to claim 12, wherein at least some of the base regions are formed in such a way that they are not in electrical contact with base contacts.
